(19) United States
(12) Patent Application Publication
(10) Pub. No.: US 2025/0210534 A1
(43) Pub. Date: Jun. 26, 2025

(54) SEMICONDUCTOR DEVICE AND MANUFACTURING METHOD OF SEMICONDUCTOR DEVICE

(71) Applicant: SHINKO ELECTRIC INDUSTRIES CO., LTD., Nagano-shi (JP)

(72) Inventor: Yoichi Nishihara, Nagano (JP)

(21) Appl. No.: 18/982,782

(22) Filed: Dec. 16, 2024

(30) Foreign Application Priority Data
Dec. 20, 2023 (JP) 2023-215149

(51) Int. Cl. H01L 23/538; H01L 21/48; H01L 23/00; H01L 25/07

(52) U.S. Cl. CPC H01L 23/5386; H01L 21/4857; H01L 21/486; H01L 23/5385; H01L 24/32; H01L 24/83; H01L 25/072; H01L 2224/32113; H01L 2224/32235; H01L 2224/8384; H01L 2924/35

(57) ABSTRACT

A semiconductor device includes an insulation base material, a wiring layer, a via, and a semiconductor element. The insulation base material includes an insulating layer including an adhesive agent layer formed on one surface of the insulating layer. The wiring layer is formed on the one surface of the adhesive agent layer. The via is separately formed from the wiring layer and penetrates through the insulating layer and the adhesive agent layer, to be connected with the wiring layer. The semiconductor element is connected, via a sintered material, with another end of the via on an opposite side of one end of the via, the one end being connected with the wiring layer, on another surface of the insulating layer.

### CROSS-REFERENCE TO RELATED APPLICATION

This application is based upon and claims the benefit of priority of the prior Japanese Patent Application No. 2023-215149, filed on Dec. 20, 2023, the entire contents of which are incorporated herein by reference.

### FIELD

The embodiment discussed herein is related to a semiconductor device and a manufacturing method of a semiconductor device.

### BACKGROUND

Conventionally, there has been known a semiconductor device in which a semiconductor element is arranged, via an adhesive agent layer, on one surface of an insulating layer constituting an insulation base material, and a wiring layer is formed on the other surface of the insulating layer. In the above-mentioned semiconductor device, the wiring layer is bonded to the semiconductor element via a via that penetrates through the insulating layer and the adhesive agent layer.

A via hole is formed in an insulating layer and an adhesive agent layer, and further electroplating is performed on the other surface of the insulating layer and an inner wall surface of the via hole so as to integrally form the wiring layer and the via.

Patent Literature 1: Japanese Laid-open Patent Publication No. 2014-027272

However, in the above-mentioned semiconductor device, there presents a problem that the connection reliability of the wiring layer is not sufficient. Specifically, in a case where a wiring layer and a via are integrally formed by electroplating, metal to be the wiring layer and the via deposits along an inner wall surface of the via hole. Thus, a concave part denting in a depth direction of the via hole is formed in the wiring layer in a position corresponding to the via hole.

Such a concave part of the wiring layer reduces the fluidity of a bonding material, such as solder, that is supplied onto the wiring layer in a case where an external component is bonded to the wiring layer, thereby leading to occurrence of a void in the bonding material on the wiring layer. In a case where a void occurs in the bonding material on the wiring layer, electric connection and mechanical connection between the wiring layer and the external component become unstable. In other words, the connection reliability in the wiring layer of the semiconductor device may reduce.

board

### SUMMARY

According to an aspect of an embodiment, a semiconductor device includes an insulation base material that includes an insulating layer including an adhesive agent layer formed on one surface of the insulating layer; a wiring layer that is formed on one surface of the adhesive agent layer; a via that is separately formed from the wiring layer and penetrates through the insulating layer and the adhesive agent layer, to be connected with the wiring layer; and a semiconductor element that is connected, via a sintered material, with another end of the via on an opposite side of one end of the via, the one end being connected with the wiring layer, on another surface of the insulating layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a semiconductor device according to an embodiment;

FIG. 2 is a flowchart illustrating a manufacturing method of the semiconductor device according to the embodiment;

FIG. 3 is a diagram illustrating a specific example of an insulation base material;

FIG. 4 is a diagram illustrating a specific example of a via hole forming process;

FIG. 5 is a diagram illustrating a specific example of a metal foil laminating process;

FIG. 6 is a diagram illustrating a specific example of a seed layer forming process;

FIG. 7 is a diagram illustrating a specific example of an electrolytic copper plating process;

FIG. 8 is a diagram illustrating a specific example of a wiring layer forming process;

FIG. 9 is a diagram illustrating a specific example of a sintered material applying process;

FIG. 10 is a diagram illustrating a specific example of a semiconductor element mounting process;

FIG. 11 is a diagram illustrating a configuration of a semiconductor device according to a modification 1 of the embodiment;

FIG. 12 is a diagram illustrating a specific example of a wiring layer forming process;

FIG. 13 is a diagram illustrating a specific example of a sintered material applying process;

FIG. 14 is a diagram illustrating a configuration of a semiconductor device according to a modification 2 of the embodiment;

FIG. 15 is a flowchart illustrating a manufacturing method of the semiconductor device according to the modification 2 of the embodiment; and

FIG. 16 is a diagram illustrating a specific example of a wiring board temporary bonding process.

### DESCRIPTION OF EMBODIMENT

Hereinafter, an embodiment of a semiconductor device and a manufacturing method of a semiconductor device disclosed in the present application will be described in detail with reference to the drawings. Note that the embodiment is not intended to limit the present invention.

### EMBODIMENT

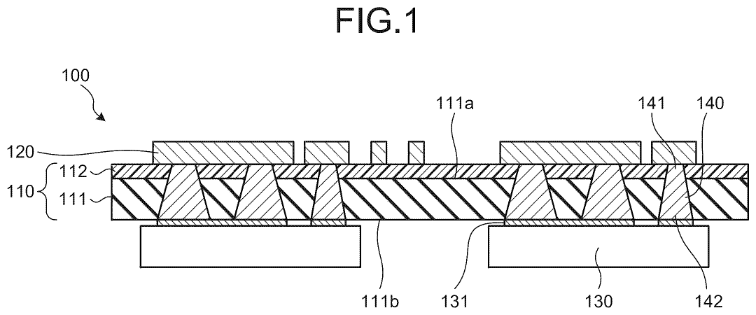

FIG. 1 is a diagram illustrating a configuration of a semiconductor device 100 according to an embodiment. In FIG. 1, a cross section of the semiconductor device 100 is schematically illustrated. The semiconductor device 100 illustrated in FIG. 1 includes an insulation base material 110, a wiring layer 120, and semiconductor elements 130.

Note that in the following description, a surface on which the wiring layer 120 of the insulation base material 110 is formed may be referred to as an “upper surface” and a surface opposite to the surface on which the wiring layer 120 is formed may be referred to as a “lower surface”, and an up-and-down direction is prescribed therewith. However, the semiconductor device 100 may be inverted upside down when manufactured and used, for example, and further may be manufactured and used in an arbitrary posture.

The insulation base material 110 is a film-shaped member constituted of an insulating layer 111 that includes an adhesive agent layer 112 on an upper surface 111a of the insulating layer 111, so as to be a base material of the semiconductor device 100. As material of the insulating layer 111, an insulation resin material may be employed, such as a polyimide-based resin, a polyethylene-based resin, and an epoxy-based resin. A thickness of the insulating layer 111 may be approximately 25 μm to 125 μm, for example. As material of the adhesive agent layer 112, a thermosetting resin may be employed, such as an epoxy-based resin, a polyimide-based resin, and a silicone-based resin. A thickness of the adhesive agent layer 112 may be approximately 10 μm to 50 μm, for example.

The wiring layer 120 is formed on an upper surface of the adhesive agent layer 112. The wiring layer 120 is formed of copper or copper alloy, for example. A thickness of the wiring layer 120 may be approximately 50 μm to 500 μm, for example. The wiring layer 120 is electrically connected to the semiconductor elements 130 by vias 140 and sintered materials 131.

The vias 140 are embedded in the insulating layer 111 and the adhesive agent layer 112 of the insulation base material 110. Each of the vias 140 penetrates through the insulating layer 111 and the adhesive agent layer 112 to be connected with the wiring layer 120. In other words, one ends 141 of the vias 140 are connected with the wiring layer 120, and other ends 142 of the vias 140 are exposed at a lower surface 111b of the insulating layer 111.

The semiconductor elements 130 are bonded to the other ends 142 of the vias 140, which are exposed at the lower surface 111b of the insulating layer 111. As the semiconductor elements 130, semiconductor element with the use of, for example, silicon (Si) or silicon carbide (SiC) may be employed. The semiconductor elements 130 may be ones with the use of gallium nitride (GaN), gallium arsenide (GaAs), or the like. For example, as the semiconductor element 130; a semiconductor element (for example, silicon tip such as CPU) that serves as an active element, an Insulated Gate Bipolar Transistor (IGBT), a Metal-Oxide-Semiconductor Field-Effect Transistor (MOSFET), a diode, or the like may be employed.

In the embodiment, via holes are formed in the insulating layer 111 and the adhesive agent layer 112, and electrolytic copper plating is performed thereon so that the vias 140 are separately formed from the wiring layer 120. In other words, the wiring layer 120 is not integrally formed with the vias 140 in a case where the vias 140 are formed in via holes of the insulating layer 111 and the adhesive agent layer 112 by electrolytic copper plating, and an interface to be a bonding surface between the wiring layer 120 and each of the vias 140 is present between the wiring layer 120 and the vias 140. The wiring layer 120 and each of the vias 140 are separately formed, and thus a concave part denting in a depth direction of a corresponding via hole is not formed in the wiring layer 120 so that a surface of the wiring layer 120 becomes a flat surface. Thus, the fluidity is kept in bonding material such as solder, which is supplied onto the wiring layer 120 in a case where an external component is bonded to the wiring layer 120, so that it is possible to reduce occurrence of a void in the bonding material. As a result, it is possible to improve the connection reliability of the wiring layer 120 with respect to the external component.

In the embodiment, the semiconductor elements 130 are bonded to the other ends 142 of the vias 140 by the sintered materials 131. Thus, it is possible to further improve bonding strength between the semiconductor elements 130 and the vias 140 compared with a case where the semiconductor elements 130 are bonded to the other ends 142 of the vias 140 by another bonding material that is different from the sintered materials 131. Note that the semiconductor elements 130 may be bonded to the other ends 142 of the vias 140 by another bonding material such as solder.

In the embodiment, each of the vias 140 has a tapered shape in which a diameter thereof increases as a position is closer to the semiconductor element 130. In other words, in each of the vias 140, a diameter of the other end 142 connected with the semiconductor element 130 is larger than a diameter of the one end 141 connected with the wiring layer 120. As described above, each of the vias 140 has a tapered shape, and thus a bonding area between the semiconductor element 130 and the corresponding via 140 increases, so that it is possible to improve bonding strength between the semiconductor elements 130 and the vias 140.

In the embodiment, edge surfaces of the other ends 142 of the vias 140 are arranged on a surface that is the same as the lower surface 111b of the insulating layer 111. Thus, an area of edge surfaces of the other ends 142 to be a bonding surface to the semiconductor element 130 increases, so that it is possible to further improve bonding strength between the semiconductor element 130 and the vias 140.

In the embodiment, edge surfaces of the other ends 142 of the vias 140 are flat surfaces. Thus, flatness of the sintered materials 131 are kept in a case where the semiconductor elements 130 are bonded to the other ends 142 of the vias 140 by the sintered materials 131, so that it is possible to further improve bonding strength between the semiconductor elements 130 and the vias 140.

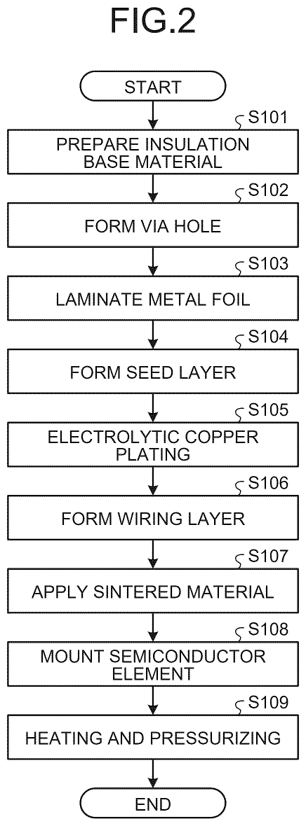

Next, a manufacturing method of the semiconductor device 100 that is configured as described above will be explained with reference to FIG. 2 while exemplifying a specific example. FIG. 2 is a flowchart illustrating a manufacturing method of the semiconductor device 100 according to the embodiment.

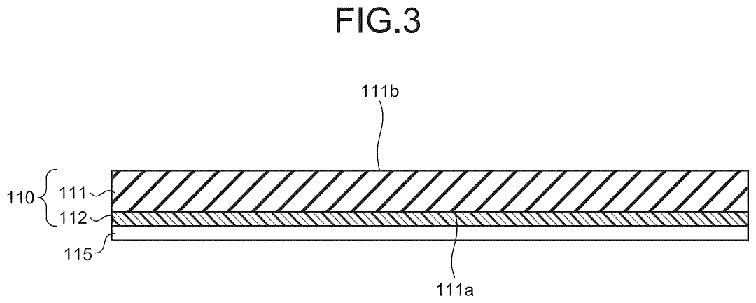

The insulation base material 110 to be a base material of the semiconductor device 100 is prepared (Step S101). Specifically, for example, as illustrated in FIG. 3, the insulation base material 110 is prepared, which is constituted of the insulating layer 111 that includes the adhesive agent layer 112 on the upper surface 111a of the insulating layer 111. FIG. 3 is a diagram illustrating a specific example of the insulation base material 110. In FIG. 3, the insulation base material 110 is illustrated while inverting it upside down. As material of the insulating layer 111, an insulation resin material such as a polyimide-based resin, a polyethylene-based resin, and an epoxy-based resin may be employed. As material of the adhesive agent layer 112, a thermosetting resin such as an epoxy-based resin, a polyimide-based resin, and a silicone-based resin may be employed. During the step in which the insulation base material 110 is prepared, the adhesive agent layer 112 is in a semi-cured state. An upper surface (namely, surface on opposite side of insulating layer 111) of the adhesive agent layer 112 is covered by a protection film 115. As the protection film 115, a polyethylene-terephthalate film having been treated with a silicone-based mold release agent or a non-silicone-based mold release agent may be employed, for example.

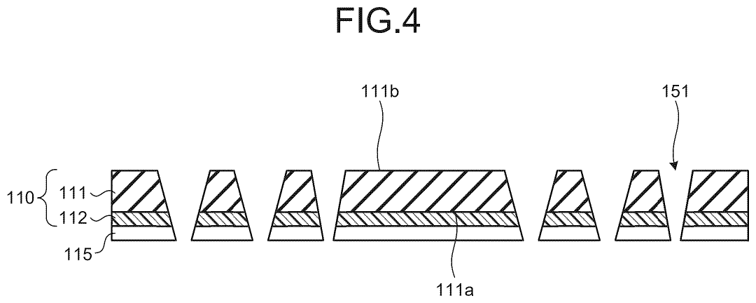

Subsequently, via holes are formed in the insulation base material 110 (Step S102). Specifically, for example, as illustrated in FIG. 4, via holes 151 are formed, each of which penetrates the insulating layer 111, the adhesive agent layer 112, and the protection film 115 in a thickness direction thereof. FIG. 4 is a diagram illustrating a specific example of a via hole forming process. Each of the via holes 151 has a tapered shape in which a diameter thereof decreases as a position is farther from the lower surface 111b of the insulating layer 111. The via holes 151 can be formed by laser machining or punching machining, for example. In this case, an upper surface (namely, surface on opposite side of insulating layer 111) of the adhesive agent layer 112 is covered by the protection film 115, so that it is possible to prevent a case where machining wastes of an insulation resin material occurred in laser machining or punching machining adhere to the upper surface of the adhesive agent layer 112.

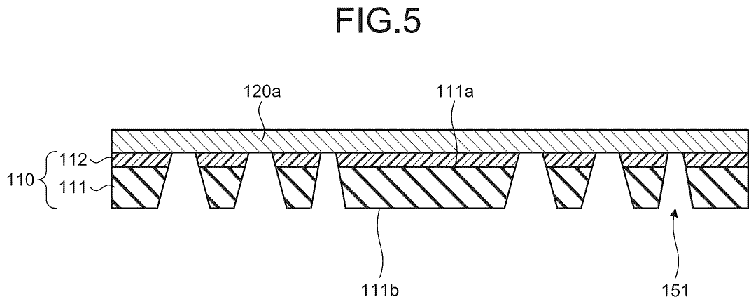

In a case where the via holes 151 are formed, a metal foil to be the wiring layer 120 is laminated on an upper surface of the adhesive agent layer 112 (Step S103). Specifically, after the protection film 115 is peeled off from an upper surface of the adhesive agent layer 112, for example, as illustrated in FIG. 5, a metal foil 120a is laminated on the upper surface of the adhesive agent layer 112. FIG. 5 is a diagram illustrating a specific example of a metal foil laminating process. The metal foil 120a is exposed at a bottom surface of the via holes 151. Similar to a thickness of the wiring layer 120, a thickness of the metal foil 120a may be approximately 50 μm to 500 μm, for example. At a step where the metal foil 120a is laminated on an upper surface of the adhesive agent layer 112, thermosetting is performed on the adhesive agent layer 112, and the metal foil 120a coheres to the adhesive agent layer 112. As material of the metal foil 120a, the metals having been exemplified as material of the wiring layer 120 may be employed. In other words, the metal foil 120a may be made of copper or copper alloy.

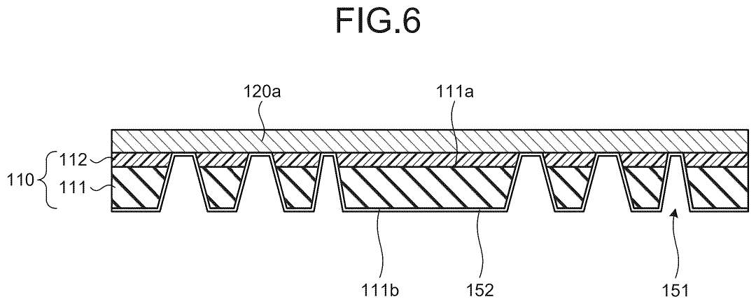

In a case where the metal foil 120a is laminated on an upper surface of the adhesive agent layer 112, electro-less copper plating is performed on the lower surface 111b of the insulating layer 111 electrolytic copper plating so as to form a seed layer (Step S104). Specifically, for example, as illustrated in FIG. 6, a seed layer 152 is formed, which continuously covers the lower surface 111b of the insulating layer 111 at around the via holes 151, inner wall surfaces of the via holes 151, and a surface of the metal foil 120a exposed at bottom surfaces of the via holes 151. FIG. 6 is a diagram illustrating a specific example of a seed layer forming process.

In a case where the seed layer 152 is formed on the lower surface 111b of the insulating layer 111, electrolytic copper plating for forming the vias 140 is performed while using the seed layer 152 as a power supply layer (Step S105). Thus, in addition to the via holes 151, electrolytic copper deposits on the lower surface 111b of the insulating layer 111.

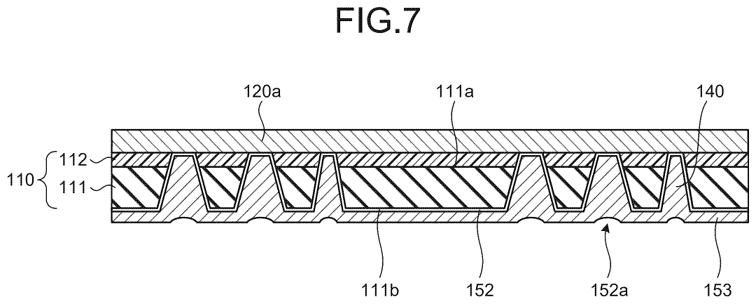

In other words, for example, as illustrated in FIG. 7, the via holes 151 are filled with electrolytic copper so as to form the vias 140, and further an electrolytic copper plating layer 153 is formed on the lower surface 111b of the insulating layer 111. FIG. 7 is a diagram illustrating a specific example of an electrolytic copper plating process. Concave parts 152a each denting in a depth direction of the corresponding via hole 151 are formed in portions of the electrolytic copper plating layer 153 which are overlapped with the via holes 151 in a plan view.

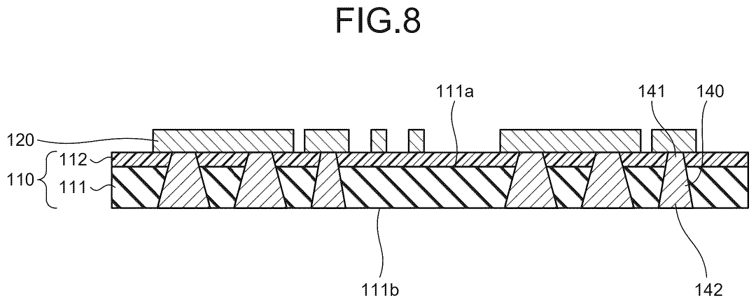

Next, the wiring layer 120 including a desired wiring pattern is formed from the metal foil 120a (Step S106). For example, the wiring layer 120 is formed from the metal foil 120a by the subtractive process. In other words, a resist layer is formed on an upper surface of the metal foil 120a, which covers a part to be left as a wiring pattern. The metal foil 120a that is exposed without being covered by a resist layer is removed by etching, for example, as illustrated in FIG. 8, and thus the wiring layer 120 is formed, which includes a desired wiring pattern and further is connected with the one ends 141 of the vias 140. FIG. 8 is a diagram illustrating a specific example of a wiring layer forming process.

In a case where a surface of the electrolytic copper plating layer 153 is configured not to be covered by a resist layer in performing etching on the metal foil 120a, etching is performed not only on the metal foil 120a that is not exposed without being covered by a resist layer but also on the electrolytic copper plating layer 153. The seed layer 152 on the electrolytic copper plating layer 153 and the lower surface 111b of the insulating layer 111 is removed by the above-mentioned etching, and thus the other ends 142 of the vias 140 are exposed at the lower surface 111b of the insulating layer 111. In this case, etching is performed under an etching condition that is adjusted such that concave parts according to the concave parts 152a of the electrolytic copper plating layer 153 are not formed on edge surfaces of the other ends 142 of the vias 140. Thus, edge surfaces of the other ends 142 of the vias 140 are flat surfaces. Moreover, etching is performed under an etching condition that is adjusted such that edge surfaces of the other ends 142 of the vias 140 are positioned on a surface that is the same surface as the lower surface 111b of the insulating layer 111. The seed layer 152 that is in contact with the vias 140 remains after etching; however, illustration thereof is omitted in FIG. 8.

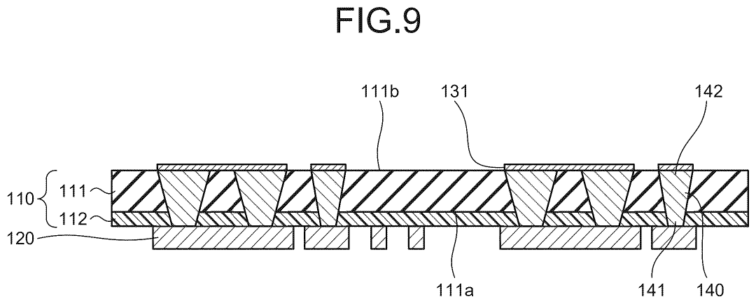

In a case where the wiring layer 120 is formed, for example, as illustrated in FIG. 9, the sintered material 131 for bonding the semiconductor elements 130 and the vias 140 is applied to edge surfaces of the other ends 142 of the vias 140 (Step S107). FIG. 9 is a diagram illustrating a specific example of a sintered material applying process. In FIG. 9, the insulation base material 110 is indicated while inverting it upside down. The sintered material 131 may be applied by printing of sintered material paste, or a dispenser may be used.

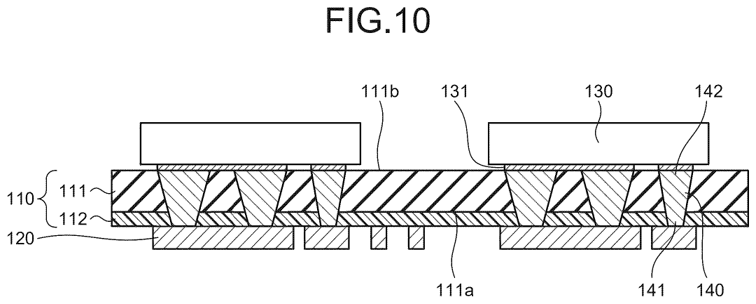

In a case where the sintered material 131 is applied to edge surfaces of the other ends 142 of the vias 140, for example, as illustrated in FIG. 10, the semiconductor elements 130 are mounted on a side of the lower surface 111b of the insulating layer 111 (Step S108), and the semiconductor elements 130 and the other ends 142 of the vias 140 are temporarily bonded by the sintered materials 131. FIG. 10 is a diagram illustrating a specific example of a semiconductor element mounting process.

Next, the sintered material 131, which is applied to edge surfaces of the other ends 142 of the vias 140, is sintered by heating and pressurizing with respect to electrodes of the semiconductor elements 130 (Step S109). Thus, at the lower surface 111b of the insulating layer 111, the semiconductor elements 130 are bonded to the other ends 142 of the vias 140 so as to obtain the semiconductor device 100.

### Modification

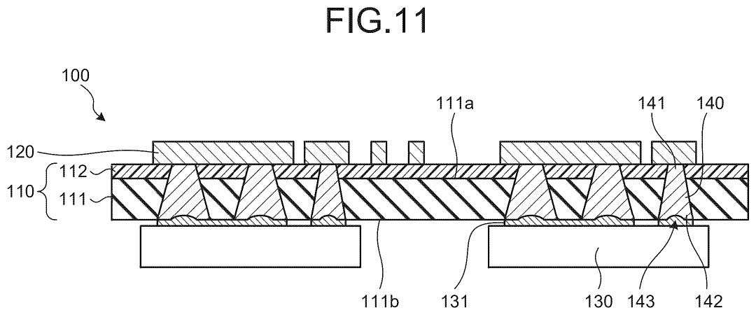

Next, various modifications according to the embodiment will be explained with reference to FIG. 11 to FIG. 16. Note that in the following various modifications, the same reference symbols are respectively provided to the same parts according to the above-mentioned embodiment so as to omit duplicated explanation.

FIG. 11 is a diagram illustrating a configuration of the semiconductor device 100 according to a modification 1 of the embodiment. The semiconductor device 100 according to the modification 1 is different from the one according to the embodiment in a shape of edge surfaces of the other ends 142 of the vias 140.

Specifically, in the modification 1, concave parts 143 are formed on edge surfaces of the other ends 142 of the vias 140. Thus, in a case where the semiconductor elements 130 are bonded to the other ends 142 of the vias 140 by the sintered material 131, a part of the sintered material 131 enters the concave parts 143 that are formed on the other ends 142 of the vias 140. As a result, anchor effects are achieved between the vias 140 and the sintered material 131, so that it is possible to improve adhesiveness of the sintered material 131 with respect to the vias 140.

Next, a manufacturing method of the semiconductor device 100 according to the modification 1 will be explained. The manufacturing method of the semiconductor device 100 according to the modification 1 is basically similar to the manufacturing method of the semiconductor device 100 illustrated in FIG. 2. The manufacturing method of the semiconductor device 100 according to the modification 1 is different from the manufacturing method of the semiconductor device 100 illustrated in FIG. 2 in contents of the wiring layer forming process (Step S106) and the sintered material applying process (Step S107). Specifically, in the wiring layer forming process

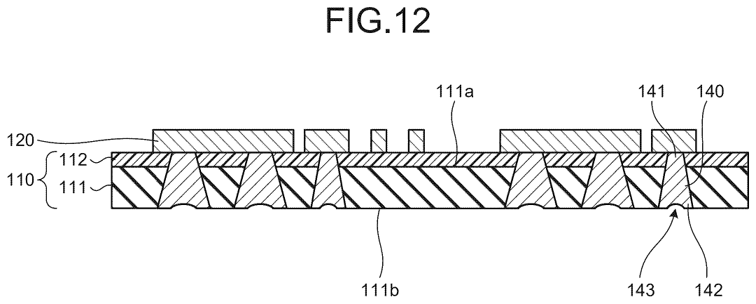

of Step S106, etching is performed on the electrolytic copper plating layer 153 under an etching condition that is adjusted such that concave parts corresponding to the concave parts 152a of the electrolytic copper plating layer 153 are formed on edge surfaces of the other ends 142 of the vias 140. Thus, for example, as illustrated in FIG. 12, the concave parts 143 are formed on edge surfaces of the other ends 142 of the vias 140. FIG. 12 is a diagram illustrating a specific example of a wiring layer forming process. Bottom surfaces of the concave parts 143 of the vias 140 have a curved shape, and a depth of the deepest part of each of the concave parts 143 is smaller than each of thicknesses of the insulating layer 111 and the adhesive agent layer 112.

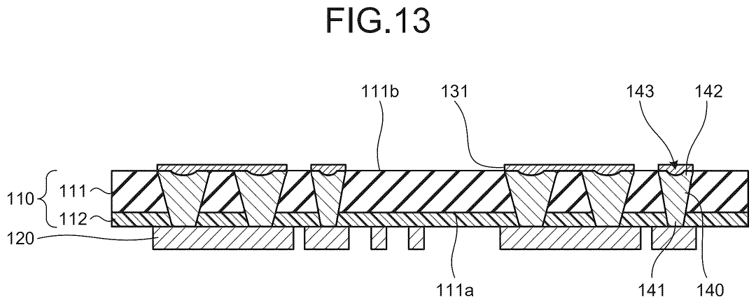

In the sintered material applying process of Step S107, for example, as illustrated in FIG. 13, a part of the applied sintered material 131 enters the concave parts 143 that are formed on the other ends 142 of the vias 140. FIG. 13 is a diagram illustrating a specific example of a sintered material applying process. A part of the sintered material 131 is retained in the concave parts 143 of the vias 140, and thus anchor effects are achieved between the vias 140 and the sintered material 131, so that it is possible to improve adhesiveness of the sintered material 131 with respect to the vias 140.

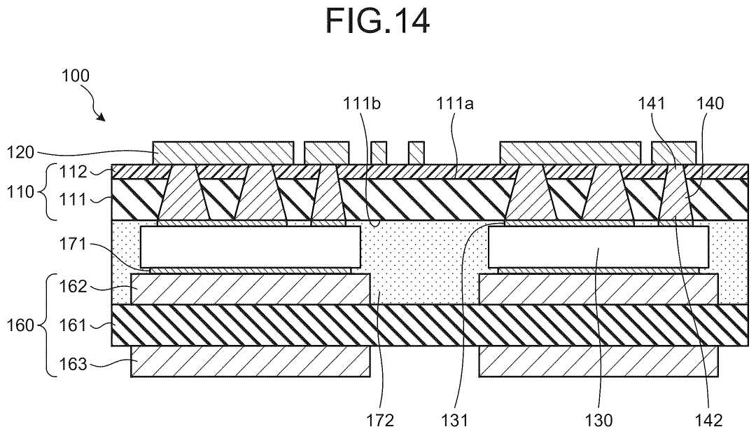

FIG. 14 is a diagram illustrating a configuration of the semiconductor device 100 according to a modification 2 of the embodiment. The semiconductor device 100 according to the modification 2 is different from the one according to the embodiment in including a wiring board 160.

Specifically, in the modification 2, the wiring board 160 is bonded to a surface (namely, lower surface) of the semiconductor element 130 on an opposite side of a surface (namely, upper surface) that is bonded to the vias 140.

The wiring board 160 includes a board 161, an upper surface pad 162, and a lower surface pad 163. The board 161 is an insulating plate-shaped member, and further is a base material of the wiring board 160. The board 161 is a ceramic board that is constituted of ceramics such as an oxide-based ceramic and a non-oxide-based ceramic. As the oxide-based ceramic, for example, aluminum-oxide (Al₂O₃), zirconia (ZrO₂), or the like may be employed. As a non-oxide-based ceramic, for example, aluminum nitride (AlN), silicon nitride (Si₃N₄), or the like may be employed.

The board 161 is not limited to a monolayer insulating member, and may be a laminated board having a multilayer structure obtained by laminating an insulating layer and a wiring layer. In a case where the board 161 is a laminated board, wiring layers interposing therebetween an insulating layer are electrically connected by a via that penetrates the above-mentioned insulating layer. As material of the insulating layer, ceramics such as an oxide-based ceramic and a non-oxide-based ceramic may be employed. As material of the wiring layer, for example, cupper or copper alloy may be employed.

The upper surface pad 162 is formed on a wiring layer on an upper surface of the board 161, and further is exposed at the upper surface of the board 161 for bonding the semiconductor element 130. In a case where a lower surface of the semiconductor element 130 is bonded to an upper surface of the wiring board 160, an electrode on a lower surface of the semiconductor element 130 is bonded to the upper surface pad 162 by a sintered material 171. As material of the upper surface pad 162, similar to the wiring layer, for example, cupper or copper alloy may be employed.

The lower surface pad 163 is formed on a wiring layer on a lower surface of the board 161. As material of the lower surface pad 163, similar to the wiring layer, for example, cupper or copper alloy may be employed.

The wiring board 160 as described above is bonded to a lower surface of the semiconductor element 130, and thus the semiconductor element 130 is arranged between the wiring board 160 and the insulation base material 110. The semiconductor element 130 arranged between the wiring board 160 and the insulation base material 110 is resin-sealed by insulation resin material 172. In other words, a space between the wiring board 160 and the insulation base material 110 is filled with the insulation resin material 172 so as to cover the semiconductor elements 130. As material of the insulation resin material 172, for example, an insulation resin material such as a polyimide-based resin and an epoxy-based resin, or a resin material obtained by mixing the above-mentioned insulation resin material with filler made of silica, alumina, etc. may be employed.

As described above, in the modification 2, the wiring board 160 is bonded to a lower surface the semiconductor elements 130, so that it is possible to improve the degree of freedom in wiring layout.

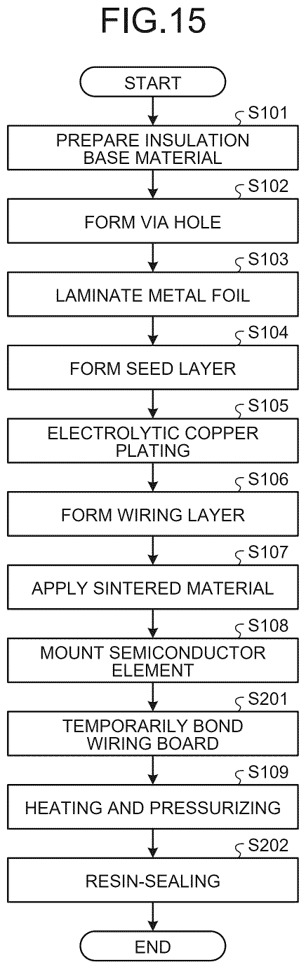

Next, a manufacturing method of the semiconductor device 100 configured as described above will be explained with reference to FIG. 15 while exemplifying a specific example. FIG. 15 is a flowchart illustrating a manufacturing method of the semiconductor device 100 according to the modification 2 of the embodiment. In FIG. 15, parts that is the same as those illustrated in FIG. 2 are provided with the same reference symbols.

In a case where the semiconductor elements 130 and the other ends 142 of the vias 140 are temporarily bonded by the sintered material 131 in processing of Step S108, lower surfaces of the semiconductor elements 130 are temporarily bonded to an upper surface of the wiring board 160 by the sintered material 171 (Step S201).

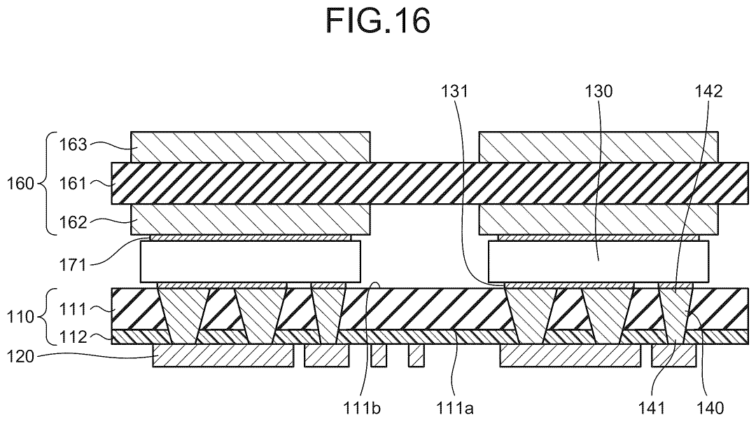

Specifically, for example, as illustrated in FIG. 16, electrodes on lower surfaces (namely, surfaces on upper side in FIG. 16) of the semiconductor elements 130 are temporarily bonded to the upper surface pads 162 by the sintered material 171. FIG. 16 is a diagram illustrating a specific example of a wiring board temporary bonding process.

The sintered material 131, which is applied to edge surfaces of the other ends 142 of the vias 140, is sintered by heating and pressurizing with respect to electrodes of the semiconductor elements (Step S109). Simultaneously with the sintering by the sintered material 131, electrodes on lower surfaces of the semiconductor elements 130 are sintered with respect to the upper surface pads 162 by the sintered material 171. In other words, the semiconductor elements 130 are bonded to the other ends 142 of the vias 140 at the lower surface 111b of the insulating layer 111, and further the wiring board 160 is bonded to lower surfaces of the semiconductor elements 130. Thus, an intermediate structure is obtained, in which the semiconductor elements 130 are interposed between the wiring board 160 and the insulation base material 110.

Next, for example, transfer molding is performed on the intermediate structure so that the semiconductor elements 130 between the wiring board 160 and the insulation base material 110 are resin-sealed by the insulation resin material 172 (Step S202). In the transfer molding, the intermediate structure is housed in a mold, and further the fluidized insulation resin material 172 is injected into the mold. Next, the insulation resin material 172 is heated up to a predetermined temperature so as to be cured. Thus, a space between the wiring board 160 and the insulation base material 110 is filled with the insulation resin material 172 and the semiconductor elements 130 are sealed so as to complete the semiconductor device 100.

As described above, a semiconductor device (as one example, semiconductor device 100) according to the embodiment includes an insulation base material (as one example, insulation base material 110), a wiring layer (as one example, wiring layer 120), a via (as one example, via 140), and a semiconductor element (as one example, semiconductor elements 130). The insulation base material includes an insulating layer (as one example, insulating layer 111) including an adhesive agent layer (as one example, adhesive agent layer 112) formed on one surface (as one example, upper surface 111a) of the insulating layer. The wiring layer is formed on the one surface (as one example, upper surface) of the adhesive agent layer. The via is separately formed from the wiring layer and penetrates through the insulating layer and the adhesive agent layer, to be connected with the wiring layer. The semiconductor element is connected, via a sintered material (as one example, sintered materials 131), with another end (as one example, another end 142) of the via on an opposite side of one end (as one example, one end 141) of the via, the one end being connected with the wiring layer on another surface (as one example, lower surface 111b) of the insulating layer. Thus, it is possible to improve the connection reliability of the wiring layer.

According to an aspect of a wiring board disclosed herein, it is possible to improve the connection reliability of a wiring layer.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A semiconductor device comprising:
an insulation base material that includes an insulating layer including an adhesive agent layer formed on one surface of the insulating layer;
a wiring layer that is formed on one surface of the adhesive agent layer;
a via that is separately formed from the wiring layer and penetrates through the insulating layer and the adhesive agent layer, to be connected with the wiring layer; and
a semiconductor element that is connected, via a sintered material, with another end of the via on an opposite side of one end of the via, the one end being connected with the wiring layer, on another surface of the insulating layer.

2. The semiconductor device according to claim 1, wherein
the via has a tapered shape whose diameter of the other end is larger than a diameter of the one end.

3. The semiconductor device according to claim 1, wherein
the other end of the via includes an edge surface positioned on a surface that is a same surface as the other surface of the insulating layer.

4. The semiconductor device according to claim 3, wherein
the edge surface includes a flat surface.

5. The semiconductor device according to claim 3, wherein
the edge surface includes a concave part.

6. The semiconductor device according to claim 1 further comprising:
a wiring board that is bonded to a surface on an opposite side of a surface of the semiconductor element which is bonded to the via.

7. A manufacturing method of a semiconductor device comprising:
forming a via hole in an insulation base material that includes an insulating layer including an adhesive agent layer formed on one surface of the insulating layer, the via hole penetrating through the insulating layer and the adhesive agent layer;
laminating a metal foil on one surface of the adhesive agent layer;
performing metal plating to form, in the via hole, a via connected with the metal foil, and further to form a plating layer on another surface of the insulating layer;
performing etching to form a wiring layer from the metal foil, and further to remove the plating layer from the other surface of the insulating layer; and
bonding a semiconductor element to another end of the via which is on an opposite side of one end of the via which is connected with the wiring layer on the other surface of the insulating layer.
